(19) United States
(12) Patent Application Publication
(10) Pub. No.: US 2007/0026575 A1
(43) Pub. Date: Feb. 1, 2007

(54) No flow underfill device and method

(76) Inventors: Sankara J. Subramanian, Chandler, AZ (US); Mitul B. Modi, Phoenix, AZ (US); Ibrahim B. Bekar, Chandler, AZ (US)

Correspondence Address: SCHWEGMAN, LUNDBERG, WOESSNER & KLUTH, P.A., P.O. BOX 2938, MINNEAPOLIS, MN, 55402, US

(21) Appl. No.: 11/167,073

(22) Filed: Jun. 24, 2005

(51) Int. Cl. H01L 21/00

(52) U.S. Cl. 438/127; 438/106

(57) ABSTRACT

A more reliable and easier to manufacture underfill assembly is shown. Underfill layers are shown that are manufacturable separately from an assembly operation. In one example, underfill layers have the ability for pick and place operations during assembly. Another advantage of underfill layers provided includes self aligning holes that aid in placing semiconductor chips over an appropriate location on a substrate. Another advantage of selected underfill layers includes pre-formed conductive plugs within an underfill layer that eliminate the need for forming solder bumps on an adjacent component surface.

### TECHNICAL FIELD

Embodiments of the present invention relate generally to the field of circuit interconnection and, in particular, selected aspects of the present invention relate to no-flow interconnection of electronic devices.

### BACKGROUND

Semiconductor chips such as processor chips are housed in chip packages, which are subsequently attached to circuit boards in the manufacture of a number of electronic devices. These devices, include personal computers, handheld computers, mobile telephones, MP3 players and other numerous information processing devices. One common configuration of input/output connections between chips, substrates, packages, and adjacent circuit boards, etc. includes grid array connection structures. In one common grid array connection structure, solder balls such as C4 connection solder structures are used to connect between grids.

There are a number of design concerns that are taken into account when forming grid arrays. High mechanical strength and reliability of the grid array connections are desirable. In a solder structure grid interconnection example, two connection surfaces with one or more solder balls in between are heated to reflow the solder and form an electrical connection. The heating process causes adjacent structures such as chips, substrates, chip packages and circuit boards to expand and contract at different rates due to differences in the coefficient of thermal expansion (CTE) in each component. The differences in CTE may cause unwanted stresses and strains in resulting products.

### BRIEF DESCRIPTION OF THE DRAWINGS

FIG. 1 shows an electronic assembly in process according to the prior art.

FIG. 2 shows an electronic assembly according to an embodiment of the invention.

FIG. 3 shows an isometric view of an underfill assembly according to an embodiment of the invention.

FIG. 4 shows an electronic assembly in process according to an embodiment of the invention.

FIG. 5 shows a cross section of an underfill assembly according to an embodiment of the invention.

FIG. 6 shows a flow diagram of a method according to an embodiment of the invention.

FIG. 7 shows an electronic device according to an embodiment of the invention.

### DETAILED DESCRIPTION

In the following detailed description of the invention reference is made to the accompanying drawings which form a part hereof, and in which are shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized, and structural, mechanical, chemical, materials choices, etc. may be made, without departing from the scope of the present invention. The following detailed description is, therefore, not to be taken in a limiting sense, and the scope of the invention should be determined with reference to the appended claims, along with the full scope of equivalents to which such claims are entitled.

One method of providing increased mechanical strength to an interconnecting region of an electronic assembly includes introduction of an epoxy underfill layer after solder balls have already been connected between two component surfaces. In one underfill process, liquid epoxy or other curable liquid is flowed into a gap between two component surfaces and around the reflowed solder connections using capillary forces to draw the liquid into the gap. The liquid epoxy is then cured to form a more robust connection between the two component surfaces and protect the solder connections from failures such as stress cracking. Such capillary flow methods can be used between chips and substrates, or between chip packages and adjacent circuit boards, between two circuit boards, etc. One drawback of using capillary flow methods is that most of the stresses in the assembly are generated during the solder reflow step, before any stress mitigating epoxy is introduced at the interface. Another drawback of using capillary flow methods includes increased manufacturing time to both introduce the epoxy, and cure the epoxy.

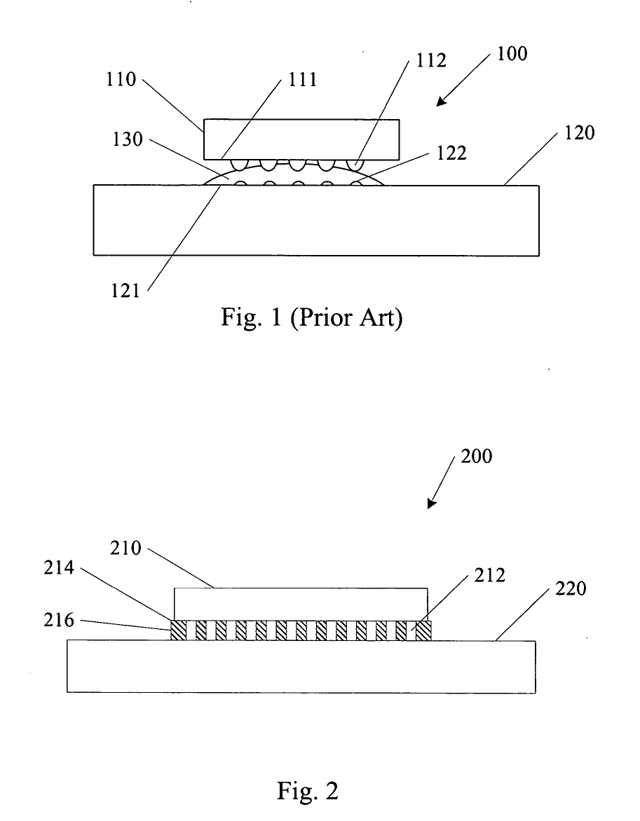

No-flow processes are sometimes used in place of capillary flow methods in operations such as chip attachment to substrates. FIG. 1 shows an electronic assembly 100 in a no-flow process. The electronic assembly 100 includes a chip 110 and a substrate 120. The chip 110 includes a first component surface 111 with a number of solder balls 112 located on the first component surface 111. The substrate 120 includes a second component surface 121 with a number of solder balls 122 located on the second component surface 121. In a current example of a no flow underfill process, an amount of uncured liquid epoxy 130 is placed on the substrate 120 over the solder balls 122. The chip 110 and associated solder balls 112 are then placed into the epoxy 130, and the solder balls 112 are aligned with corresponding solder balls 122 on the substrate 120. The solder balls 112 and 122 are then reflowed to produce an electrical connection between the chip 110 and the substrate 120. The epoxy 130 is also cured to form a bond between the first component surface 111 and the second component surface 121.

One disadvantage of this method includes the manufacturing time and cost of individual application of each pool of epoxy. Another disadvantage of this method includes the possibility of solder balls 112 and 122 not contacting each other, leaving an electrical open. Although pressure can be used to force solder balls 112 and 122 into contact during manufacturing, a disadvantage of using force includes the possibility of solder balls 112 and 122 slipping alongside each other causing misalignment of the connection.

FIG. 2 shows an electronic assembly 200 according to an embodiment of the invention. A semiconductor chip 210, such as a processor chip is shown coupled to a substrate 220. An underfill layer 214 is shown between the semiconductor chip 210 and the substrate 220, with a number of conductive pathways 212 through the underfill layer 214. As will be discussed in more detail below, the underfill layer 214 according to embodiments of the invention provides a number of advantages such as more reliable manufacturing of conductive pathways 212. In one embodiment, the underfill layer 214 includes distinctive physical features such as substantially vertical edges 216, in contrast to edges formed by surface tension of liquid epoxy 130 as shown in FIG. 1.

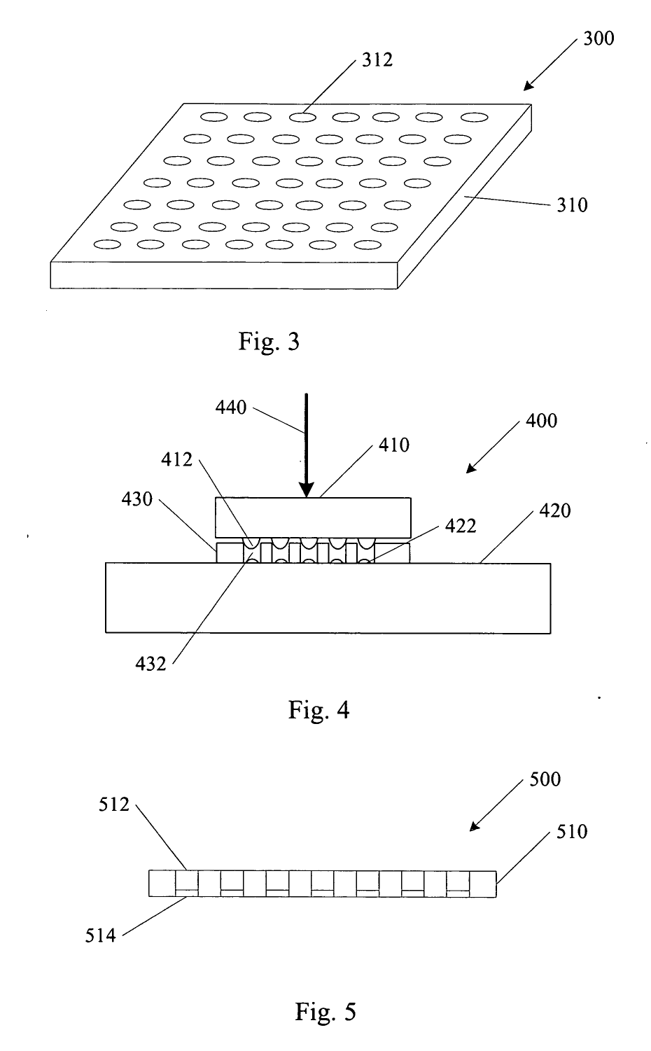

FIG. 3 shows an underfill assembly 300 that can be used in embodiments such as electronic assembly 200 from FIG. 2, or other devices as described below. The underfill assembly 300 includes a partially cured polymer layer 310. A number of through thickness holes 312 are provided within the partially cured polymer layer 310.

In one embodiment, the partially cured polymer layer 310 includes a partially cured epoxy layer. Although an epoxy layer is described, other polymer layers capable of partial curing or partial conversion from one set of mechanical properties to another are within the scope of the invention. In one embodiment, the partially cured epoxy is cured to an amount that is sufficient for tactile handling by an assembly person, or assembly robot, etc. In one embodiment, some level of flowing of the partially cured polymer layer 310 is acceptable while still maintaining an ability for tactile handling. In one embodiment, some level of flowing or other deformation helps to wet adjacent solder structures prior to a cure operation.

In one embodiment, the partially cured epoxy is cured to an amount between 70% and 100%. One of ordinary skill in the art, having the benefit of the present disclosure will recognize that an amount of partial curing is dependent upon the specific chemistry and associate properties of a given polymer or epoxy. One of ordinary skill in the art, having the benefit of the present disclosure will also recognize that the amount of partial curing can be determined without undue experimentation.

In one embodiment the number of through thickness holes is determined by a number of electrical connections in corresponding devices such as a semiconductor chip and a substrate. In one embodiment, a pattern of through thickness holes in the partially cured polymer layer 310 is formed to line up with corresponding solder structures on a semiconductor chip package. One possible number of solder structures includes an array of C4 structures. In one embodiment, alignment is facilitated for a ball grid array.

FIG. 4 shows one embodiment of a manufacturing operation to form an electronic assembly 400. The underfill assembly 430 is picked from one location and placed over solder structures 422 on a substrate 420. The solder structures 412 on a chip 410 are then placed in the exposed portion of holes 432. Although assembly is described as placing the underfill assembly 430 on the substrate solder structures 422 first, the invention is not so limited. In one embodiment, the underfill assembly is placed over the chip solder structures 412 first. An advantage of having pre-made holes 432 in the underfill assembly 430 includes reduced restrictions to contact between the chip solder structures 412 and the substrate solder structures 422. The holes 432 also provide an aligning function, thus reducing or eliminating the need for external aligning structures in manufacturing tooling.

In one embodiment, to ensure contact between the chip solder structures 412 and the substrate solder structures 422, a force is applied along direction 440 during processing. Once the chip solder structures 412 and the substrate solder structures 422 are in contact, the solder is reflowed to form an electrical connection between the chip 410 and the substrate 420. In one embodiment, the electronic assembly 400 is heated to a temperature sufficient to reflow the solder. In one embodiment, the reflow operation is carried out concurrently with a further curing operation of the underfill assembly 430, thus further reducing manufacturing time.

Because no underfill material was located in holes 432 between the chip solder structures 412 and the substrate solder structures 422, the resulting reflowed solder is more likely to connect, and less likely to entrap either the chip solder structures 412 or the substrate solder structures 422 and leave an electrical open. Additionally, because no underfill material was located in holes 432 between the chip solder structures 412 and the substrate solder structures 422 little or no force is needed along direction 440 to form a reliable connection. Less force during this operation reduces the chance of misalignment due to solder structures 412, 422 being forced past each other prior to reflow.

In contrast to a pool of liquid epoxy 130 as shown in FIG. 1, the underfill assembly 430 can be formed separately from an attachment operation. Because they are formed with sufficient mechanical stability for handling, embodiments of underfill assemblies shown in the present disclosure can be formed in mass production to reduce manufacturing costs. For example, large sheets of partially cured polymer can be stamped, or cut with holes punched or cut, etc. Further, the partial curing can be done before assembly of the electronic assembly 400, thus reducing final curing time at this stage of manufacturing.

FIG. 5 shows a cross section of an underfill assembly 500 according to an embodiment of the invention. Similar to embodiments described above, the underfill assembly 500 includes a partially cured polymer layer 510. A number of through thickness holes 512 are included within the partially cured polymer layer 510. FIG. 5 includes a conductive plug 514 within a portion of at least some of the through thickness holes 512. In one embodiment, the conductive plug 514 includes a solder plug. Although the conductive plugs 514 shown in FIG. 5 only fill a bottom portion of the holes 512, the invention is not so limited. For example, in one embodiment, the conductive plugs 514 fill an entire amount of the holes 512.

Embodiments using the conductive plug 514 include the advantage of eliminating solder bumps on one or more connection surfaces such as the substrate or the chip. Similar to embodiments described above, the underfill assembly 500 can be mass produced, and is manufactured separately from putting together an assembly such as shown in FIG. 4. In one embodiment, the conductive plug 514 is pre-assembled in the partially cured polymer layer 510, thus the conductive plug 514 includes at least one exposed surface prior to placing between a chip and a substrate.

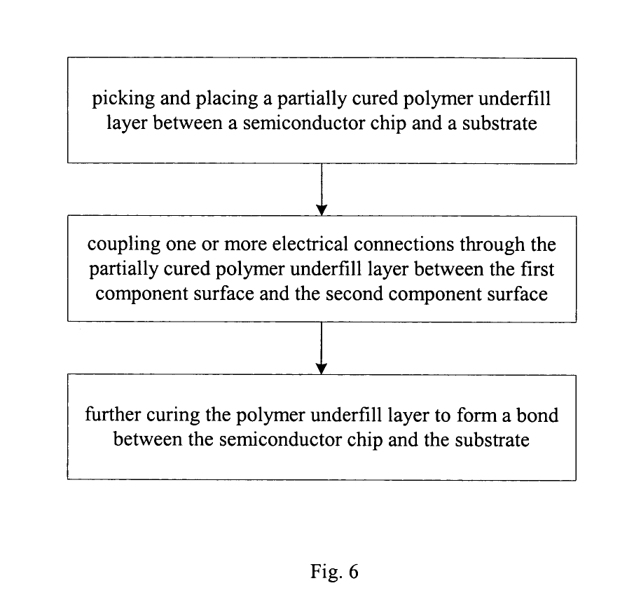

FIG. 6 shows one example of a method of formation similar to methods discussed above. In one embodiment, due to partial curing, a polymer underfill layer is capable of tactile handling, thus a pick and place operation is possible. As shown in FIG. 6, in one embodiment, the partially cured polymer underfill layer is placed between a semiconductor chip and a substrate. In one embodiment, one or more electrical connections are coupled through the partially cured polymer underfill layer. Although reflowing solder is discussed above, other electrical connections such as curing a conductive epoxy are also possible within the scope of embodiments of the invention. In one embodiment, the partially cured polymer layer is further cured to form a bond between the semiconductor chip and the substrate. The bond provides the necessary mechanical strength for a reliable and robust connection to counteract coefficient of thermal expansion stresses.

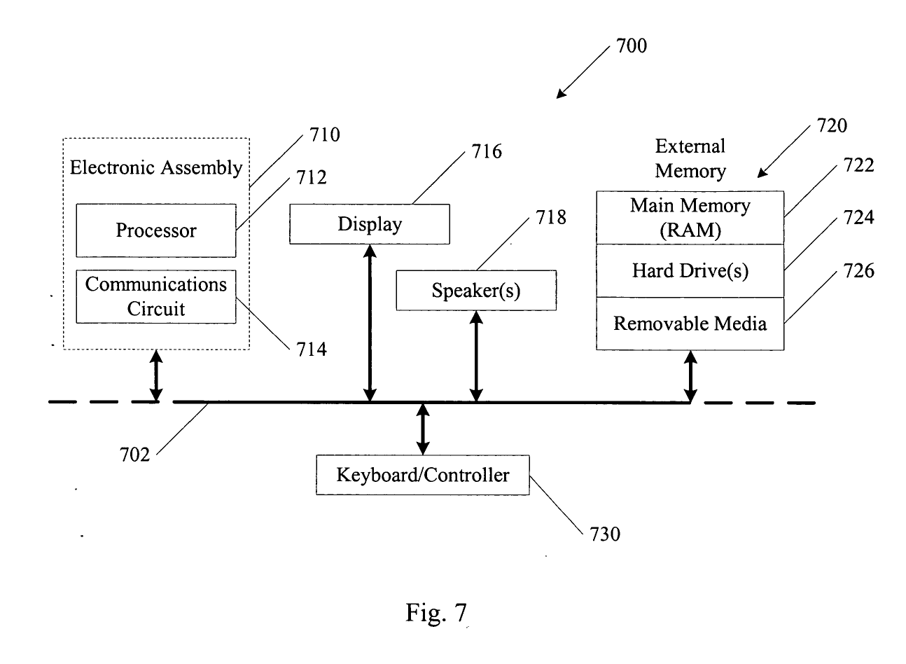

An example of an electronic device using semiconductor chips and underfill layers is included to show an example of a higher level device application for the present invention. FIG. 7 is a block diagram of an electronic device 700 incorporating at least one electronic assembly 710 utilizing an underfill assembly and method in accordance with at least one embodiment of the invention. Electronic device 700 is merely one example of an electronic system in which embodiments of the present invention can be used. Examples of electronic devices 700 include, but are not limited to personal computers, mobile telephones, personal data assistants, MP3 or other digital music players, etc. In this example, electronic device 700 comprises a data processing system that includes a system bus 702 to couple the various components of the system. System bus 702 provides communications links among the various components of the electronic device 700 and can be implemented as a single bus, as a combination of busses, or in any other suitable manner.

An electronic assembly 710 is coupled to system bus 702. The electronic assembly 710 can include any circuit or combination of circuits. In one embodiment, the electronic assembly 710 includes a processor 712 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), or any other type of processor or processing circuit.

Other types of circuits that can be included in electronic assembly 710 are a custom circuit, an application-specific integrated circuit (ASIC), or the like, such as, for example, one or more circuits (such as a communications circuit 714) for use in wireless devices like mobile telephones, pagers, personal data assistants, portable computers, two-way radios, and similar electronic systems. The IC can perform any other type of function.

The electronic device 700 can also include an external memory 720, which in turn can include one or more memory elements suitable to the particular application, such as a main memory 722 in the form of random access memory (RAM), one or more hard drives 724, and/or one or more drives that handle removable media 726 such as compact disks (CD), digital video disk (DVD), and the like.

The electronic device 700 can also include a display device 716, one or more speakers 718, and a keyboard and/or controller 730, which can include a mouse, trackball, game controller, voice-recognition device, or any other device that permits a system user to input information into and receive information from the electronic device 700.

A more reliable and easier to manufacture underfill assembly is shown. One advantage of underfill layers provided above includes the ability to manufacture beforehand and pick and place the underfill layers during assembly. Another advantage of underfill layers provided above includes self aligning holes that aid in placing semiconductor chips over an appropriate location on a substrate. Another advantage of selected embodiments shown above includes pre-formed conductive plugs within an underfill layer that eliminate the need for forming solder bumps on an adjacent component surface.

Although selected advantages are detailed above, the list is not intended to be exhaustive. Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of embodiments described above. It is to be understood that the above description is intended to be illustrative, and not restrictive. Combinations of the above embodiments, and other embodiments will be apparent to those of skill in the art upon reviewing the above description. The scope of the invention includes any other applications in which the above structures and fabrication methods are used. The scope of the invention should be determined with reference to the appended claims, along with the full scope of equivalents to which such claims are entitled.

What is claimed is:

1. A method, comprising:
picking and placing a partially cured polymer underfill layer between a semiconductor chip and a substrate;
coupling one or more electrical connections through the partially cured polymer underfill layer between the semiconductor chip and the substrate; and
further curing the polymer underfill layer to form a bond between the semiconductor chip and the substrate.

2. The method of claim 1, wherein picking and placing a partially cured polymer underfill layer includes picking and placing a partially cured epoxy underfill layer.

3. The method of claim 1, wherein picking and placing the partially cured polymer underfill layer between the semiconductor chip and the substrate includes picking and placing a partially cured polymer underfill layer between a processor chip and a substrate.

4. The method of claim 2, wherein picking and placing the partially cured epoxy underfill layer between the semiconductor chip and the substrate includes placing holes in the partially cured epoxy underfill layer around solder bumps.

5. The method of claim 1, wherein further curing the polymer underfill layer includes heating the semiconductor chip and the substrate and concurrently reflowing a solder connection between the semiconductor chip and the substrate.

6. A method of forming an electronic device, comprising:
picking and placing a partially cured polymer underfill layer between a processor chip and a substrate;
coupling one or more input/output connections through the partially cured polymer underfill layer between the processor chip and the substrate;
further curing the polymer underfill layer to form a bond between the processor chip and the substrate; and
coupling a wireless communication circuit to the processor chip.

7. The method of claim 6, further including coupling a hard drive to the processor chip.

8. The method of claim 6, coupling one or more input/output connections includes reflowing a solder connection.

9. The method of claim 6, wherein coupling the wireless communication circuit includes coupling a mobile telephone communication circuit.

10. An underfill assembly, comprising:
a partially cured polymer film;
at least one conductive plug coupled to the partially cured polymer film having an exposed surface on at least one side of the partially cured polymer film.

11. The underfill assembly of claim 10, wherein the partially cured polymer film includes a partially cured epoxy film.

12. The underfill assembly of claim 11, wherein the partially cured epoxy film includes an epoxy film cured 70% or more.

13. The underfill assembly of claim 10, wherein the conductive plug includes solder.

14. An underfill assembly, comprising:
a partially cured polymer film;
a number of holes passing through the partially cured polymer film, wherein the number of holes are patterned to line up with corresponding solder structures on a semiconductor chip package.

15. The underfill assembly of claim 14, wherein the solder structures include an array of C4 structures.

16. The underfill assembly of claim 14, wherein the partially cured polymer film includes an epoxy film.

17. The underfill assembly of claim 16, wherein the partially cured epoxy film includes an epoxy film cured 70% or more.

18. The underfill assembly of claim 14, wherein the number of through thickness holes are sized to provide an interference fit with corresponding solder structures on the semiconductor chip package.
